(19) United States
(12) Patent Application Publication
(10) Pub. No.: US 2018/0192510 A1
(43) Pub. Date: Jul. 5, 2018

(54) WIRING SUBSTRATE AND METHOD FOR MANUFACTURING THE SAME

(71) Applicant: TOPPAN PRINTING CO., LTD., Tokyo (JP)

(72) Inventor: Tetsuyuki TSUCHIDA, Tokyo (JP)

(73) Assignee: TOPPAN PRINTING CO., LTD., Tokyo (JP)

(21) Appl. No.: 15/859,234

(22) Filed: Dec. 29, 2017

Related U.S. Application Data
(63) Continuation of application No. PCT/JP2016/003218, filed on Jul. 6, 2016.

(30) Foreign Application Priority Data
Jul. 10, 2015 (JP) 2015-138985

(51) Int. Cl. H05K 1/02; H01L 23/13; H01L 23/15; H01L 23/498; H01L 23/00; H01L 21/48; H05K 1/03; H05K 3/02

(52) U.S. Cl. CPC H05K 1/0271; H01L 23/13; H01L 23/15; H01L 23/49822; H01L 23/49816; H01L 23/562; H01L 27/14618; H01L 21/4857; H05K 1/0306; H05K 1/0274; H05K 3/02; H01L 2224/16235; H01L 2924/3512; H01L 24/16

(57) ABSTRACT

A wiring substrate that helps prevent cracking of a base material at the time of formation of a light transmissive portion, has high light transmittance, and allows formation of fine wiring, and a method for manufacturing the same. The wiring substrate includes: a base material with light transmittance; a laminated body formed by laminating a metal layer and a resin layer on at least one side of the base material; and a light transmissive portion as an opening provided in part of the laminated body. The wiring substrate is characterized in that at least part of side surfaces defining the light transmissive portion is formed from the resin layer, and adjacent the surface of the base material, part of the metal layer is adjacent to the resin layer constituting at least part of the side surfaces defining the light transmissive portion and is disposed to surround the resin layer.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Application No. PCT/JP2016/003218, filed on Jul. 6, 2016, which is based upon and claims the benefit of priority of Japanese Patent Application No. 2015-138985, filed on Jul. 10, 2015, the entireties of which are hereby incorporated by reference.

### TECHNICAL FIELD

The present invention relates to a wiring substrate and a method for manufacturing the same.

### BACKGROUND ART

In recent years, semiconductor devices using semiconductor chips and external connection members have been employed in various technical fields for electronic devices, automobiles, and others. Additionally, as electronic devices have become more functional, compact, and lightweight, there has been a need for smaller semiconductor packages, higher pin counts, and finer-pitched external terminals, thereby leading to an increasing demand for high-density wiring substrates. Conventional core materials have been organic materials typified by a glass epoxy resin, but there is a limit to the formation of finer-line wiring on a core with these materials. For connection with a sensor device, for example, it is necessary to use a core material effective in protecting the sensor and high in light transmittance. In such circumstances, increasing attention has been paid to the development of a wiring substrate allowing such fine wiring and based on glass with high transparency and high refractive index, and the application of such a wiring substrate to optical devices is expected.

### CITATION LIST

### Patent Literature

PTL 1: JP 2005-5488 A

Using a non-photosensitive interlayer insulating resin for use in conventional semiconductor package substrates makes it difficult to manufacture a wiring substrate with a light transmissive portion. In addition, in the case where the wiring substrate is based on glass, when the resin on the glass is dissolved and removed using a laser for formation of the light transmissive portion, the glass may be cracked due to the heat from the laser beam.

In addition, in the case where the resin is removed from the glass by radiation, when the glass is immersed in a potassium permanganate solution to clean resin residues off the core, part of the glass dissolves and fogs up to and lowers the refractive index and the light transmittance.

Moreover, the multilayer wiring substrate disclosed in PTL 1 is provided with a wiring layer via an insulation layer, which imposes a limit on the formation of fine wiring. Further, since the insulation layer is formed from polyimide, the use of glass as the base material may provide insufficient adhesion between the polyimide and glass.

### SUMMARY OF THE INVENTION

### Technical Problem

An object of the present invention is to provide a wiring substrate that helps prevent cracking of a base material at the time of formation of a light transmissive portion, has high light transmittance, and allows formation of fine wiring, and a method for manufacturing the same.

### Solution to Problem

The present invention provides a wiring substrate including: a base material with light transmittance; a laminated body formed by laminating a metal layer and a resin layer on at least one side of the base material; and a light transmissive portion as an opening provided in part of the laminated body, characterized in that at least part of side surfaces defining the light transmissive portion is formed from the resin layer, and adjacent the surface of the base material, part of the metal layer is adjacent to the resin layer constituting at least part of the side surfaces defining the light transmissive portion and is disposed to surround the resin layer.

The present invention also provides a wiring substrate including: a base material with light transmittance; a laminated body formed by laminating a metal layer and a resin layer on at least one side of the base material; and a light transmissive portion as an opening provided in part of the laminated body, characterized in that adjacent the surface of the base material, part of the metal layer is disposed to surround the light transmissive portion.

The present invention also provides a method for manufacturing a wiring substrate having a light transmissive portion, including: a step of forming a metal layer to cover a formation area of the light transmissive portion and a circumference thereof on a base material with light transmittance; a step of forming a resin layer to cover the formed metal layer; a step of selectively removing part of the resin layer on the formation area of the light transmissive portion to form an opening portion; and a step of removing the metal layer exposed from the opening portion.

### Advantageous Effects of the Invention

According to the wiring substrate and the method for manufacturing the same of the present invention, it is possible to achieve a wiring substrate that prevents cracking of a base material at the time of formation of a light transmissive portion, has high light transmittance, and allows formation of fine wiring, and a method for manufacturing the same.

### BRIEF DESCRIPTION OF THE DRAWINGS

FIG. 1 is a diagram describing a semiconductor device manufactured using a wiring substrate according to an embodiment.

FIG. 2 is a diagram describing the wiring substrate according to the embodiment.

FIG. 3 is a diagram describing another wiring substrate according to the embodiment.

FIGS. 4(a) to 4(o) are diagrams describing a process for manufacturing the wiring substrate according to the embodiment.

FIGS. 5(a) to 5(h) are diagrams describing a process for manufacturing the other wiring substrate according to the embodiment.

### DESCRIPTION OF REPRESENTATIVE EMBODIMENTS

A preferred embodiment and other embodiments of the present invention will be described in detail below with reference to the attached drawings. In the following description, identical elements or elements with identical functionality will be given the same reference signs, and duplicated explanations thereof will be omitted. The following is a description of the case in which two resin layers are formed on one side of a base material. It is to be understood that the embodiments and Examples disclosed are representative of the present invention and that the present invention is not necessarily limited to the embodiments and Examples.

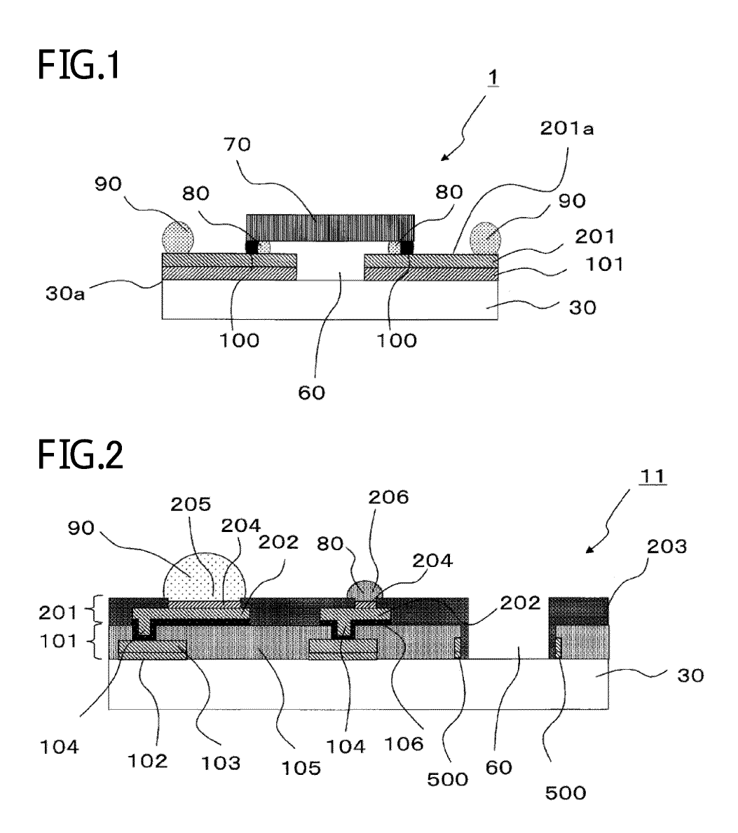

FIG. 1 is a diagram describing a semiconductor device manufactured using a wiring substrate according to the embodiment. As illustrated in FIG. 1, a semiconductor device 1 includes a laminated body 101, a laminated body 201, a light transmissive portion 60, a base material 30, bonding terminals 80, external connection terminals 90, a component 70, and sealing resins 100. The laminated body 101, the laminated body 201, and the light transmissive portion 60 will be described in detail later.

The component 70 is, for example, an integrated circuit (IC or LSI) having a transistor or a diode that is formed on the surface of a semiconductor substrate and is approximately cuboidal. The semiconductor substrate is, for example, a substrate mainly based on an inorganic substance, such as a silicon substrate (Si substrate), a gallium nitride substrate (GaN substrate), or a silicon carbide substrate (SiC substrate). In this embodiment, the semiconductor substrate is a silicon substrate. The coefficient of thermal expansion (CTE) of the component 70 formed using a silicon substrate is about 2 to 4 ppm/K (for example, 3 ppm/K). The coefficient of linear expansion according to the embodiment refers to a length varying responsive to the temperature rise within a temperature range of 20° C. or more to 260° C. or less, for example. Alternatively, the component 70 may be, for example, a solid state imaging sensor such as a CMOS sensor or a CCD sensor.

The base material 30 is formed from a material with the property of light transmission (transparency), for example. The thickness of the base material 30 is 0.05 mm or more to 1 mm or less, for example. The base material 30 has a main surface 30a approximately rectangular, circular, or oval, for example. The range of wavelengths of light transmitted by the base material 30 may preferably be, for example, preferably 100 nm or more to 20000 nm or less, more preferably or 300 nm or more to 1100 nm or less. The base material 30 may be glass, for example. In the case of using glass for the base material 30, there are no limitations on the kinds of components of the glass, the component ratio, and the method for manufacturing the glass. The glass may be, for example, non-alkali glass, alkali glass, borosilicate glass, quartz glass, sapphire glass, photosensitive glass, or the like. The manufacturing methods include a float method, downdraw method, fusion method, updraw method, and roll-out method, and the glass may be manufactured using any of these methods. The coefficient of linear expansion of the glass is preferably close to the coefficient of linear expansion of the component 70 described above, which may be, for example, preferably be −1 ppm/K or more to 10.0 ppm/K or less, more preferably or 0.5 ppm/K or more to 5.0 ppm/K or less. The maximum height roughness Rz of the main surface 30a of the base material 30 under JIS B 0601:2013 may preferably be, for example, 0.01 μm or more to 5 μm or less, more preferably or 0.1 μm or more to 3 μm or less. Setting the maximum height roughness Rz of the main surface 30a of the base material 30 to 0.01 μm or more makes it possible to reduce cost for preparing the base material 30. Setting the maximum height roughness Rz of the main surface 30a of the base material 30 to 5 μm or less makes it possible to prevent a disconnection or short-circuit in a conductive layer resulting from the asperities on the main surface 30a and achieve high-density packaging with fine wiring.

The bonding terminals 80 and the external connection terminals 90 are both provided on the laminated body 201. The bonding terminals 80 are electrically connected to the component 70. The bonding terminals 80 and the external connection terminals 90 are formed by, for example, soldering of Sn, Sn—Pb, Sn—Ag, Sn—Cu, Sn—Ag—Cu, or Sn—Bi. When the bonding terminals 80 and the external connection terminals 90 are formed by soldering, a Ni plating, Au plating, or Sn plating may be applied, or pre-soldering treatment, for example, organic film coating processing such as organic solderability preservative (OSP), may be applied to a portion of a metal layer exposed at a main surface 201a of the laminated body 201, before the formation of the bonding terminals 80 and the external connection terminals 90.

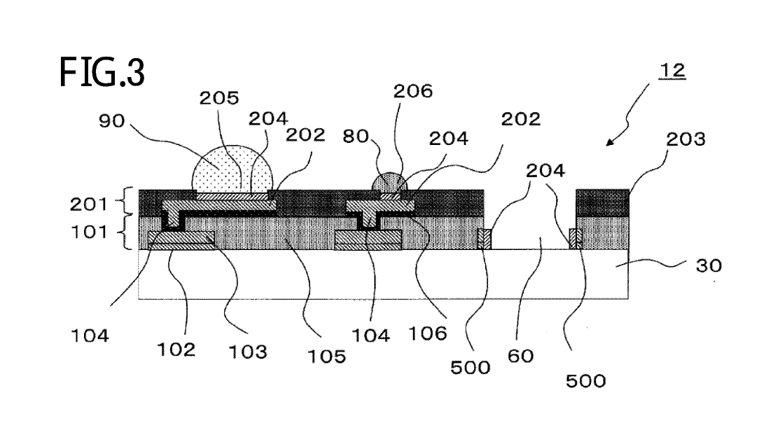

FIGS. 2 and 3 are diagrams describing the wiring substrate according to the embodiment. As illustrated in FIGS. 2 and 3, each of a wiring substrate 11 according to the embodiment and another wiring substrate 12 according to the embodiment includes the base material 30, the laminated body 101, the laminated body 201, the light transmissive portion 60, the bonding terminal 80, the external connection terminal 90, and a metal layer 500. The laminated body 101 includes a seed layer 102, a metal layer 103, part of a metal layer 202, part of a seed layer 106, part of vias 104, and a resin layer 105. The laminated body 201 includes part of the metal layer 202, part of the seed layer 106, part of the vias 104, a resin layer 203, and a surface treatment layer 204. The base material 30 may have a via and the via may have a metal therein. Further, the number of laminated layers can be increased by increasing the number of laminated body formed from resin layers, metal layers, and the like. In addition, a treatment layer may be provided between the laminated body 101 and the base material 30 for enhancement of adhesion therebetween.

The surface treatment layer 204 is formed from, for example, a single layer or a composite layer with a thickness of 0.001 μm or more to 3 μm or less. For example, Au, Pd, Sn, Cu, or Ni can be used for a single layer, and Au/Ni, Au/Pd, or Au/Pd/Ni can be used for a composite layer. The methods for forming a metal layer include a plating method typified by wet processing and a sputtering method typified by vacuum processing. In terms of tact time, the plating method is desired and either electroless plating or electrolytic plating can be used. In the case where the surface treatment layer 204 is an electroless Ni plating film, the Ni plating film may include inorganic substances such as phosphorus and boron. In addition, in the case where the surface treatment layer 204 is an electroless Pd plating film, the Pd film may include W other than the foregoing inorganic substances so that an Au/electroless Pd—P/electroless Ni—P film can be formed, for example. The surface treatment layer 204 may be an organic film applied such as by using OSP.

The seed layer 102 and the seed layer 106 can be formed, for example, by using singly Cu, Al, Ti, Cr, Mo, W, Ta, Au, Ir, Ru, Pd, Pt, AlSi, AlSiCu, AlCu, NiFe, indium tin oxide (ITO), indium zinc oxide (IZO), aluminum doped zinc oxide (AZO), ZnO, lead zirconate titanate (PZT), TiN, Cu3N4 or the like, or combining them. These layers have a thickness of 0.0001 μm or more to 10 μm or less, for example.

The metal layer 103 and the metal layer 202 are electrically conductive layers that are formed from a metal such as Au, Cu, or Ni, for example, and are provided in the resin layer 105 and the resin layer 203. The metal layer 202 is electrically connected to the seed layer 102 and the metal layer 103 through the vias 104 in the laminated body 101. The metal layer 103 and the metal layer 202 have a thickness of 1 μm or more to 20 μm or less, for example. Part of the metal layer 202 may be formed from a metal paste as a composite material of metal and organic sub stance.

The metal layer 500 is formed from part of the seed layer 102 and part of the metal layer 103, which constitutes a portion that is not removed by etching but left at the time of formation of the light transmissive portion 60. The metal layer 500 has a thickness of 1.0001 μm or more to 30 μm or less, for example.

The resin layer 105 and the resin layer 203 include, for example, a resin material such as epoxy resin, polyimide, maleimide resin, polyethylene terephthalate, polyphenylene oxide, liquid polymer, anti-reflection layer, infrared cutoff layer, or silicone, or a composite material of them. The resin layers 105 on the wiring substrate 11 and the wiring substrate 12 may be formed from either a photosensitive material or a non-photosensitive material. The resin layer 203 on the wiring substrate 11 is formed from a photosensitive material. The resin layer 203 on the wiring substrate 12 may be formed from either a photosensitive material or a non-photosensitive material. The resin layer 105 has a thickness of 5 μm or more to 50 μm or less, for example. The resin layer 203 has a thickness of 5 μm or more to 50 μm or less, for example.

An opening portion 205 and an opening portion 206 in the resin layer 203 may be equal in shape and size. Alternatively, the opening portion 205 may be larger than the opening portion 206 or the opening portion 205 may be smaller than the opening portion 206.

As illustrated in FIG. 3, in the wiring substrate 12, the surface treatment layer 204 is formed on the light transmissive portion side of the metal layer 500.

(Method for Manufacturing the Wiring Substrate 11)

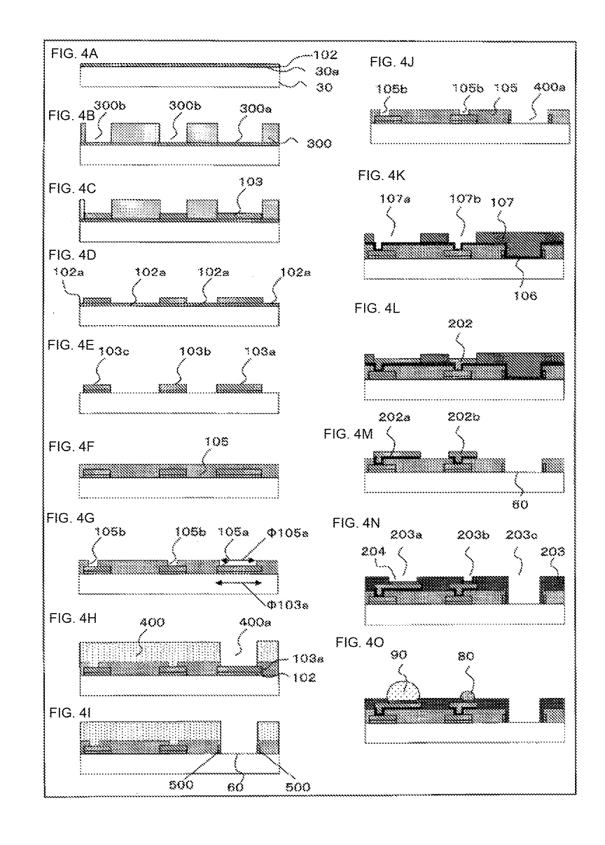

A method for manufacturing the wiring substrate 11 according to the embodiment will be described with reference to FIGS. 4(a) to 4(o).

First, as illustrated in FIG. 4(a), the seed layer 102 is applied to one side of the base material 30. The seed layer 102 is formed using a well-known technique such as sputtering, CVD, or electroless plating. For example, the seed layer 102 is formed from a Cu layer, a Cu layer with Ni plating, a Cu layer with Au plating, a Cu layer with solder plating, an Al layer, or an Ag/Pd alloy layer, or the like. In this embodiment, a Cu layer is used from the standpoint of cost, electrical characteristics, and ease of manufacture.

Next, as illustrated in FIG. 4(b), a resin layer 300 is formed on the seed layer 102. The resin layer 300 is formed using a well-known technique such as a printing method, a vacuum pressing method, a vacuum lamination method, a roll lamination method, a spin coat method, a dye coat method, a curtain coat method, or a roller coat method. Opening portions 300a and 300b are formed in the resin layer 300 by removing part of the resin layer through laser irradiation or photolithography. The opening portion 300a is to be a light transmissive portion. In this embodiment, a photosensitive resin formable by photolithography is used from the standpoint of cost, electrical characteristics, and ease of manufacture.

Next, as illustrated in FIG. 4(c), the metal layer 103 is formed in the opening portions 300a and 300b. The metal layer 103 is formed using a printing method, an electroless plating method, or an electrolytic plating method. In this embodiment, the electrolytic plating method is used and the metal layer 103 is a Cu layer from the standpoint of cost, electrical characteristics, and ease of manufacture.

Next, the resin layer 300 is removed as illustrated in FIG. 4(d), and then a seed layer 102a is removed from the portions without the metal layer 103 to obtain metal layers 103a, 103b, and 103c as illustrated in FIG. 4(e). The seed layer 102a is removed by wet etching or dry etching, for example. That is, the wiring pattern in this embodiment is formed by a semi-additive process. The semi-additive process refers to a method for obtaining a wiring pattern by forming a seed layer such as a Cu layer, forming a resist with a desired pattern on the seed layer, thickening the exposed portions of the seed layer by electrolytic plating or the like, removing the resist, and then etching the thin seed layer.

Next, as illustrated in FIG. 4(f), the resin layer 105 is formed to cover the base material 30 and the metal layers 103a, 103b, and 103c. The resin layer 105 is formed using a well-known method such as a printing method, a vacuum pressing method, a vacuum lamination method, a roll lamination method, a spin coat method, a dye coat method, a curtain coat method, or a roller coat method. In this embodiment, the vacuum lamination method or vacuum press method is used from the standpoint of ease of manufacture.

Next, as illustrated in FIG. 4(g), an opening portion 105a is formed in the resin layer 105 on the metal layer 103a, and opening portions 105b are formed in the resin layer 105 on the metal layers 103b and 103c. When the resin layer 105 is photosensitive, the opening portion 105a and the opening portion 105b are formed by photolithography or laser. When the resin layer 105 is non-photosensitive, the opening portion 105a and the opening portion 105b are formed by radiation. In this case, a diameter φ105a of the opening portion 105a needs to be smaller than a diameter φ103a of the metal layer 103a. This prevents damage to the base material 30 to avoid cracking of the base material 30 when it is made of glass, as described later. In addition, the metal layer 103a has the effect of releasing heat, and therefore the base material 30, when it is made of glass and has no metal layer 103a, might have cracks.

Next, as illustrated in FIG. 4(h), a resin layer 400 is provided to protect the opening portions 105b and form an opening portion 400a. There is no limitation on the sizes of the opening portions 105a and the opening portion 400a. When the resin layer 400 is photosensitive, the opening portion 400a is formed by photolithography or laser. When the resin layer 400 is non-photosensitive, the opening portion 400a is formed by laser. In this embodiment, a photosensitive resin formable by photolithography is used from the standpoint of cost, electrical characteristics, and ease of manufacture.

Next, as illustrated in FIG. 4(i), the metal layer 103a and the seed layer 102 are removed from the opening portion 400a to form the light transmissive portion 60. The metal layer 103a and the seed layer 102 may be removed by wet etching or dry etching. From the standpoint of cost and ease of manufacture, wet etching is employed. In this case, the residual metal layer 103a and seed layer 102 after the etching form the metal layer 500 on the outer periphery of the light transmissive portion 60. Next, as illustrated in FIG. 4(j), the resin layer 400 is separated. The resin layer is separated and removed in an alkaline solution, for example.

Next, as illustrated in FIG. 4(k), the seed layer 106 is applied. The seed layer 106 is formed by, for example, a well-known technique such as sputtering method, a CVD method, or an electroless plating method. For example, the seed layer 106 is formed from a Cu layer, a Cu layer with Ni plating, a Cu layer with Au plating, a Cu layer with solder plating, an Al layer, or an Ag/Pd alloy layer, or the like. In this embodiment, a Cu layer is used from the standpoint of cost, electrical characteristics, and ease of manufacture. Then, the same process as the one for the resin layer 400 described above is performed to form a resin layer 107 on the seed layer 106 and provide an opening portion 107a and an opening portion 107b in the resin layer 107.

Next, as illustrated in FIG. 4(l), the metal layer 202 is formed in the opening portion 107a and the opening portion 107b. Then, the resin layer 107 is separated and removed in an alkali solution, for example, and the unnecessary portions of the seed layer 106 are removed by etching to obtain the wiring substrate illustrated in FIG. 4(m).

Next, as illustrated in FIG. 4(n), the resin layer 203 is formed, and then an opening portion 203a, an opening portion 203b, and an opening portion 203c are provided. The resin layer 203 is made from a photosensitive resin, and the opening portion 203a, the opening portion 203b, and the opening portion 203c are formed by photolithography. The resin layer 203 constituting the inner wall of the opening portion 203c is in contact with the inner periphery of the metal layer 500. In addition, the surface treatment layer 204 is provided on the metal layer 202 in the opening portion 203a and the opening portion 203b. A bonding terminal 80 and an external connection terminal 90 are provided as illustrated in FIG. 4(o). Thus, the wiring substrate 11 according to the embodiment can be obtained.

(Method for Manufacturing the Wiring Substrate 12)

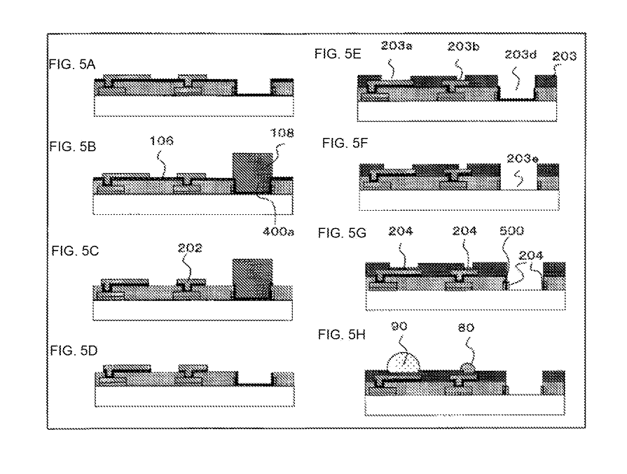

A method for manufacturing the other wiring substrate 12 according to the embodiment will be described with reference to FIGS. 5(a) to 5(h). The process for manufacturing the wiring substrate 12 has the same steps as those of the method for manufacturing the wiring substrate 11 described in FIGS. 4(a) to 4(l), and descriptions thereof will be omitted here.

As illustrated in FIG. 4(l), the metal layer 202 is formed in the opening portion 107a and the opening portion 107b, and then the resin layer 107 is separated and removed in an alkaline solution, for example, as illustrated in FIG. 5(a).

Next, as illustrated in FIG. 5(b), the resin layer 108 is formed in the opening portion 400a. Then, as illustrated in FIG. 5(c), the seed layer 106 is dissolved and removed by etching from the portions without the metal layer 202 and the resin layer 108.

Next, as illustrated in FIG. 5(d), the resin layer 108 is separated in an alkaline solution. Then, as illustrated in FIG. 5(e), the resin layer 203 is formed, and then the opening portion 203a, the opening portion 203b, and the opening portion 203d are provided. When the resin layer 203 is photosensitive, the opening portion 203a, the opening portion 203b, and the opening portion 203d are formed by photolithography or laser. When the resin layer 203 is non-photosensitive, the opening portion 203a, the opening portion 203b, and the opening portion 203d are formed laser.

Next, as illustrated in FIG. 5(f), the seed layer 106 is removed from the opening portion 203d by etching to provide an opening portion 203e. Then, as illustrated in FIG. 5(g), the surface treatment layer 204 is provided on the metal layer 202 in the opening portion 203a and the opening portion 203b and on the light transmissive unit side of the metal layer 500. Then, as illustrated in FIG. 5(h), the bonding terminals 80 and the external connection terminals 90 are provided. Thus, the wiring substrate 12 according to the embodiment can be obtained.

According to the wiring substrate and the method for manufacturing the same in this embodiment, when the light transmissive portion 60 is formed, the opening portion 400a is provided in the resin layer 105 on the metal layer 103a by photolithography or laser irradiation, and then the metal layer 103a in the opening portion 400a is removed by etching. Therefore, the resin or the metal layer formed directly on the base material 30 is not removed by laser irradiation, which makes it possible to prevent damage to the base material 30 during formation of the light transmissive portion 60. In addition, using glass for the base material 30 can avoid cracking of the base material 30. Further, there is no need to clean off resin residues after laser irradiation performed during formation of the light transmissive portion 60, eliminating the need to immerse the base material 30 in a potassium permanganate solution, thus preventing part of the glass being dissolved and fogged. Additionally, the direct formation of the metal layer on the base material allows fine wiring. This makes it possible to obtain a wiring substrate with high light transmittance and capable of fine wiring.

In addition, since the coefficient of linear expansion of the base material is −1 ppm/K or more to 10 ppm/K or less, the coefficient of linear expansion of the component and the coefficient of linear expansion of the base material are close to each other. This makes it possible to prevent a positional gap at the time of mounting the component on the wiring substrate. In addition, the glass base material can be made at lower cost and with higher strength, and can be easily increased in size. Further, the roughness of the surface of the base material can be easily adjusted.

The metal layer and the component of the wiring substrate are connected to each other via a connection terminal including solder. Accordingly, in the event of a positional gap between the metal layer and the component of the wiring substrate, it is possible to fill the gap by the connection terminal including solder, and prevent a connection failure between the component and the laminated body of the wiring substrate. The connection terminal of the wiring substrate may include gold. This improves the electrical conductivity of the connection terminal and retards the corrosion of the connection terminal. In addition, the laminated body acts as an external connection member for connection to the semiconductor chip, which makes it possible to manufacture separately the semiconductor chip and the wiring substrate having the external connection member. Accordingly, the laminated body can be used to improve the manufacture efficiency of the semiconductor device.

### EXAMPLES

The present invention will be described in more detail by the following examples. However, the present invention is not limited to these examples.

### Example 1 of the Wiring Substrate 11

In Example 1 of the wiring substrate 11, first, the seed layer 102 was formed on the main surface 30a of the base material 30 as illustrated in FIGS. 4(a) to 4(o). As the base material 30, glass (OA-10G (manufactured by Nippon Electric Glass Co., Ltd.) with a thickness of 0.5 mm) was used. The coefficient of linear expansion of the base material 30 was about 4 ppm/K. The seed layer 102 was made from a copper sputtered film. Next, the resin layer 300 made from a photosensitive dry film resist (25 μm) was used and patterned such that the diameters of the opening portion 300a and the opening portion 300b were respectively φ10000 μm and φ300 m and then the metal layer 103 was provided with a thickness of 10 μm by electrolytic copper plating in the opening portion 300a and the opening portion 300b. After separation of the resin layer 300, the unnecessary portions of the seed layer 102a were removed to obtain the metal layers 103a, 103b, and 103c (about 10 μm thick) formed by electrolytic copper plating and a copper sputtered film. Next, as the resin layer 105, GX-T31 produced by Ajinomoto Fine-Techno Co., Inc. was formed with a thickness of 20 μm by the vacuum lamination method, and the opening portion 105a and the opening portion 105b were provided respectively with φ5000 μm and φ20 μm by UV-YAG laser. Then, as the resin layer 400, a photosensitive dry film resist (25 μm) was provided, and the φ4850-μm opening portion 400a was provided by photolithography. The metal layer 103a was dissolved and removed by a liquid mixture of sulfuric acid and aqueous hydrogen peroxide, and the resin layer 400 was separated to obtain the substrate illustrated in FIG. 4(j).

Next, Ti (100 nm) and Cu (500 nm) were laminated as the seed layer 106, and a photosensitive dry film resist (25 μm) was provided as the resin layer 107, and the opening portion 107a and the opening portion 107b were provided with diameters of φ500 μm and φ300 respectively, by photolithography. The metal layer 202 was provided with a thickness of 10 μm on the seed layer 106 by electrolytic copper plating to obtain the substrate illustrated in FIG. 4(l). After separation of the resin layer 107, the copper layer was removed by a liquid mixture of sulfuric acid and aqueous hydrogen peroxide, and the titanium layer was removed by a titanium etching liquid. Then, a photosensitive solder resist layer was provided with a thickness of 20 μm as the resin layer 203, and then the opening portion 203a, the opening portion 203b, and the opening portion 203c were provided. Then, an electroless Ni/Au plating process was performed such that the thicknesses of the surface treatment layer 204 in the opening portion 203a and the opening portion 203b were respectively 3 μm and 0.05 μm. Finally, solder balls of Sn-3 wt % Ag-0.5 wt % Cu with φ500 μm and φ120 μm were respectively mounted on the surface treatment layer 204 in the opening portion 203a and the opening portion 203b at a peak temperature of 260° C. to obtain the external connection terminal 90 and the bonding terminal 80. Accordingly, the wiring substrate 11 with the light transmissive portion illustrated in FIG. 2 was obtained.

For the wiring substrate 11 according to Example 1, it has been verified that a wiring pattern of line/space=2/2 μm could be formed on the main surface 30a of the base material 30.

Additionally, in order to evaluate the optical characteristics of the wiring substrate 11 according to Example 1, a φ20000-μm evaluation opening portion was formed using the same process as the one for forming the light transmissive portion 60 according to Example 1.

The spectrometric analysis of the evaluation opening portion revealed that there was agreement with the base material 30 in light transmittance and haze within a range of 5% or less. In Example 1, since the resin directly formed on the glass was not to be removed by laser at the time of formation of the light transmissive portion 60, there was no need to immerse the glass in a potassium permanganate solution to clean resin residues off the glass. Accordingly, there was no reduction in refractive index and light transmittance that would be caused by part of the glass being dissolved and fogged.

### Example 2 of the Wiring Substrate 12

In Example 2 of the wiring substrate 12, first, the substrate illustrated in FIG. 4(l) was obtained using the same manufacturing method as that according to Example 1. Next, the resin layer 107 was separated, and then a photosensitive dry film resist was formed as the resin layer 108 in the opening portion 400a. Then, from the seed layer 106 including the Cu layer and the Ti layer, the Cu layer was removed using a liquid mixture of sulfuric acid and aqueous hydrogen peroxide, and the Ti layer was removed using a titanium etching liquid. Then, after separation of the resin layer 108 by an alkaline fluid, a photosensitive solder resist layer was provided with a thickness of 20 μm as the resin layer 203, and the opening portion 203a, the opening portion 203b, and the opening portion 203d were provided. Then, from the seed layer 106 formed from the Cu layer and the Ti layer in the opening portion 203d, the Cu layer was removed using a liquid mixture of sulfuric acid and aqueous hydrogen peroxide, and the Ti layer was removed by a titanium etching liquid to obtain the opening portion 203e. Then, as the surface treatment layer 204, an organic film was applied by the OSP process to the opening portion 203a, the opening portion 203b, and the light transmissive portion side of the metal layer 500. Finally, solder balls of Sn-3 wt % Ag-0.5 wt % Cu with diameters of φ500 μm and φ120 μm, respectively, were mounted on the surface treatment layer 204 in the opening portion 203a and the opening portion 203b at a peak temperature of 260° C. to obtain the external connection terminal 90 and the bonding terminal 80. Accordingly, the wiring substrate 12 with the light transmissive portion illustrated in FIG. 3 was obtained.

For the wiring substrate 12 of Example 2, it has been verified that a wiring pattern of line/space=2/2 μm could be formed on the main surface 30a of the base material 30.

Additionally, in order to evaluate the optical characteristics of the wiring substrate 12 according to Example 2, a φ20000-μm evaluation opening portion was formed using the same process as the one for forming the light transmissive portion 60 according to Example 2.

The spectrometric analysis of the evaluation opening portion revealed that there was agreement with the base material 30 in light transmittance and haze within a range of 5% or less. In Example 2 as well, since the resin directly formed on the glass was not to be removed by laser at the time of formation of the light transmissive portion 60, there was no need to immerse the glass in a potassium permanganate solution to clean off resin residues from the glass. Accordingly, there was no reduction in refractive index and light transmittance that would be caused by part of the glass being dissolved and fogged.

(Semiconductor Device)

Next, the component 70 was mounted on the obtained wiring substrate 11 and wiring substrate 12. The component 70 has a bump electrode with a Sn-3.5Ag solder layer on the tip of a Cu post. The coefficient of linear expansion of the component 70 was about 3 ppm/K. The bump electrode of the component 70 was aligned with the connection terminals 80 of the wiring substrate 11 and the wiring substrate 12, and the component 70 was press-fitted to the wiring substrate 11 and the wiring substrate 12 and then heated. After that, the outer peripheries of the connection terminals 80 were sealed using the sealing resins 100. Accordingly, the semiconductor device 1 illustrated in FIG. 1 was obtained.

### INDUSTRIAL APPLICABILITY

The wiring substrate and the method for manufacturing the same of the present invention can be used for glass core wiring substrates applicable to optical devices.

### REFERENCE SIGNS LIST

1 . . . Semiconductor device; 11, 12 . . . Wiring substrate; 30, 30a . . . Core; 60 . . . Light transmissive portion; 70 . . . Component; 80 . . . Bonding terminal; 90 . . . External connection terminal; 101 . . . Laminated body; 102 . . . Seed layer; 103, 103a, 103b, 103c . . . Metal layer; 104 . . . Via, 105 . . . Resin layer; 105a, 105b . . . Opening portion; 106 . . . Seed layer; 107 . . . Resin layer; 108 . . . Resin layer; 201, 201a . . . Laminated body; 202 . . . Metal layer; 203 . . . Resin layer; 203a, 203b, 203c, 203d, 203e . . . Opening portion; 204 . . . Surface treatment layer; 300 . . . Resin layer; 300a, 300b . . . Opening portion; 400 . . . Resin layer; 400a . . . Opening portion; 500 . . . Metal layer

What is claimed is:

1. A wiring substrate comprising:
a base material with light transmittance;
a laminated body formed by laminating a metal layer and a resin layer on at least one side of the base material; and
a light transmissive portion as an opening provided in part of the laminated body, characterized in that
at least part of side surfaces defining the light transmissive portion is formed from the resin layer, and
adjacent the surface of the base material, part of the metal layer is adjacent to the resin layer constituting at least part of the side surfaces defining the light transmissive portion and is disposed to surround the resin layer.

2. A wiring substrate comprising:
a base material with light transmittance;
a laminated body formed by laminating a metal layer and a resin layer on at least one side of the base material; and
a light transmissive portion as an opening provided in part of the laminated body, characterized in that
adjacent the surface of the base material, part of the metal layer is disposed to surround the light transmissive portion.

3. The wiring substrate of claim 1, characterized in that the coefficient of linear expansion of the base material is −1 ppm/K or more to 10 ppm/K or less.

4. The wiring substrate of claim 1, characterized in that the base material is glass.

5. The wiring substrate of claim 2, characterized in that the coefficient of linear expansion of the base material is −1 ppm/K or more to 10 ppm/K or less.

6. The wiring substrate of claim 2, characterized in that the base material is glass.

7. A method for manufacturing a wiring substrate having a light transmissive portion, comprising:
a step of forming a metal layer to cover a formation area of the light transmissive portion and a circumference thereof on a base material with light transmittance;
a step of forming a resin layer to cover the formed metal layer;
a step of selectively removing part of the resin layer on the formation area of the light transmissive portion to form an opening portion; and
a step of removing a portion of the metal layer exposed from the opening portion.
